(19) United States
(12) Patent Application Publication
(10) Pub. No.: US 2011/0031106 A1
(43) Pub. Date: Feb. 10, 2011

(54) METHOD FOR FABRICATING LEAD FRAME OF LIGHT EMITTING DIODE

(75) Inventor: Shang-Ho Hung, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: EVERLIGHT ELECTRONICS CO., LTD., Taipei (TW)

(21) Appl. No.: 12/769,655

(22) Filed: Apr. 29, 2010

(30) Foreign Application Priority Data
Aug. 4, 2009 (TW) 98126226

(51) Int. Cl. C23C 14/34; C25F 5/00

(52) U.S. Cl. 204/192.1; 205/640

(57) ABSTRACT

A method for fabricating lead frames of light emitting diodes (LEDs) including following steps is provided. First, a conductive frame tape is provided. The conductive frame tape includes a plurality of conductive frames arranged along an extending direction of the conductive frame tape. Each of the conductive frames has a first connection portion adapted to carry an LED chip. Next, a plurality of first sputter layers are selectively sputtered onto the conductive frame tape through at least one target, and the first sputter layers are formed on the first connection portions, respectively.

### CROSS-REFERENCE TO RELATED APPLICATION

This application claims the priority benefit of Taiwan application serial no. 98126226, filed on Aug. 4, 2009. The entirety of the above-mentioned patent application is hereby incorporated by reference herein and made a part of specification.

### BACKGROUND OF THE INVENTION

1. Field of the Invention

The invention is generally related to a method for fabricating a lead frame. More particularly, the invention is related to a method for fabricating a lead frame of a light emitting diode (LED).

2. Description of Related Art

Rarely appearing in an LED independently, an LED chip of an LED is usually dependent upon conductive frames or various leads for connections to an external power source. The material for the conductive frames of the LED typically comprises copper and iron. In order to prevent the oxidation of copper or iron from affecting the electrical connections of the chip to the external power source, a layer of silver is typically coated on the conductive frame, thereby improving the electrical connection with the conductive frames for the metal lines connecting the chip and the conductive frames.

In conventional techniques, the conductive frames are silver coated by performing an electroplating process. However, the electroplating process has the following disadvantages:

1. The electroplating process has a complicated processing steps and a long fabrication duration, thereby limiting the output per unit time.

2. Since the process steps require water in each step, water costs are increased due to the heavy water utilization.

3. In order to adhere to the environmental standards, electroplating and waste water cleanup require centralized collection and treatment, thereby increasing the management costs for waste water.

4. Due to rising environmental concerns in many countries around the world, licenses necessary to perform electroplating may be hard to acquire.

5. Since the electroplating technique cannot selectively plate only the required portions of the conductive frames, an entire conductive frame needs to be silver plated. Consequently, a significant amount of silver formula is wasted, thereby increasing costs.

6. The electroplating process causes an overly large variability in the thickness of the plated film.

### SUMMARY OF THE INVENTION

Aspects of the invention provide a method for fabricating a lead frame of an LED, in which the method includes simple fabrication processes, a large output per unit time, a low water and equipment cost, adherence to environmental concerns, and less requirement for sputter materials.

According to one embodiment of the invention, the method for fabricating the lead frame of the LED includes the following steps. First, a conductive frame tape is provided. The conductive frame tape includes a plurality of conductive frames arranged along an extending direction of the conductive frame tape. Each of the conductive frames has a first connection portion adapted to carry an LED chip. Next, a plurality of first sputter layers are selectively sputtered onto the conductive frame tape through at least one target, and the first sputter layers are respectively formed on the first connection portions, in which a mask is disposed between the target and the conductive frame tape, and the mask has a plurality of openings for exposing the first connection portions.

In one embodiment of the invention, a second sputter layer is formed on the mask while selectively sputtering the first sputter layers onto the conductive frame tape.

In one embodiment of the invention, after selectively sputtering the first sputter layers onto the conductive frame tape, the method further includes performing an electrolytic process to recover the second sputter layer on the mask.

In one embodiment of the invention, each of the first connection portions includes a chip carrying area and a wire bonding area. The chip carrying area is adapted to carry the LED chip. The wire bonding area is adapted to connect with a terminal of a conductive line, and another terminal of the conductive line is connected with the LED chip.

In one embodiment of the invention, the material of first sputter layers comprises silver.

In one embodiment of the invention, while selectively sputtering the first sputter layers onto the conductive frame tape, the method further includes moving the conductive frame tape with respect to the target.

In one embodiment of the invention, before selectively sputtering the first sputter layers onto the conductive frame tape, the method further includes cleaning the conductive frame tape and baking the conductive frame tape.

In one embodiment of the invention, after selectively sputtering the first sputter layers onto the conductive frame tape, the method further includes measuring a thickness of the first sputter layers.

In one embodiment of the invention, after selectively sputtering the first sputter layers onto the conductive frame tape, the method further includes inspecting an outer appearance of the first sputter layers.

In one embodiment of the invention, each of the conductive frames further includes a second connection portion. While selectively sputtering the first sputter layers onto the conductive frame tape through the target, the method further includes selectively sputtering a plurality of third sputter layers onto the conductive frame tape through the target or at least one other target, and respectively forming the third sputter layers on the second connection portions.

In summary, according to embodiments of the invention, since the sputter layers are sputtered onto the conductive frame tape for fabricating the lead frame of the LED, the fabrication steps are simple and high output and use a smaller amount of water, and the sputter layers have a more uniform thickness. Furthermore, since the method for fabricating the lead frame of the LED according to the embodiments of the invention selectively sputters the sputter layers onto the conductive frame tape, a larger amount of sputter material can be saved, thereby effectively reducing manufacturing costs.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B are schematic views illustrating the steps for fabricating a lead frame of a light emitting diode (LED) in accordance with one embodiment of the invention.

FIG. 2A is a top view of a conductive frame tape depicted in FIG. 1A.

FIG. 2B is a top view of a target, a mask and a conductive frame tape depicted in FIG. 1B.

FIG. 3 is a schematic cross-sectional view illustrating an electrical connection depicted in FIG. 1A between a first connection portion and a chip.

FIG. 4 is a schematic view illustrating a method for fabricating a lead frame of an LED in accordance with another embodiment of the invention.

FIG. 5 is a schematic cross-sectional view illustrating a method for fabricating a lead frame of an LED in accordance with another embodiment of the invention.

### DESCRIPTION OF EMBODIMENTS

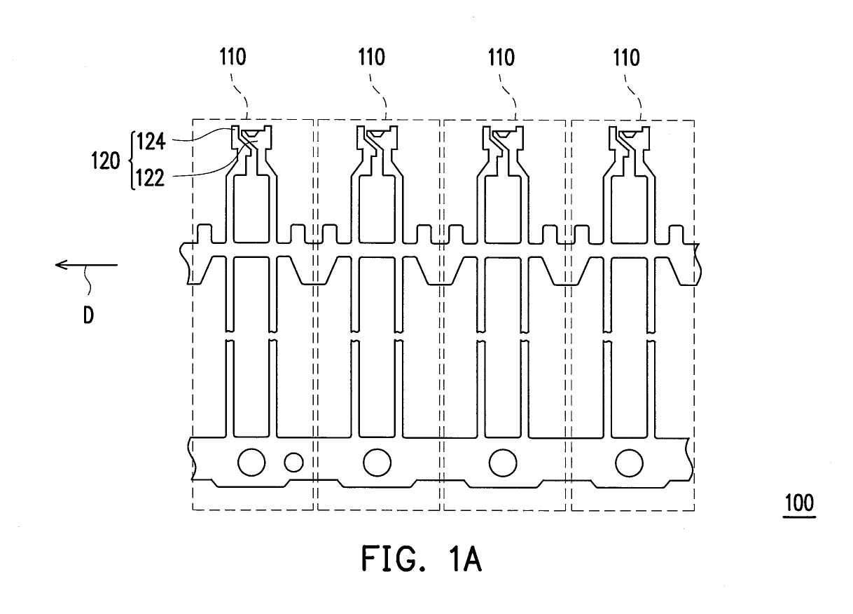

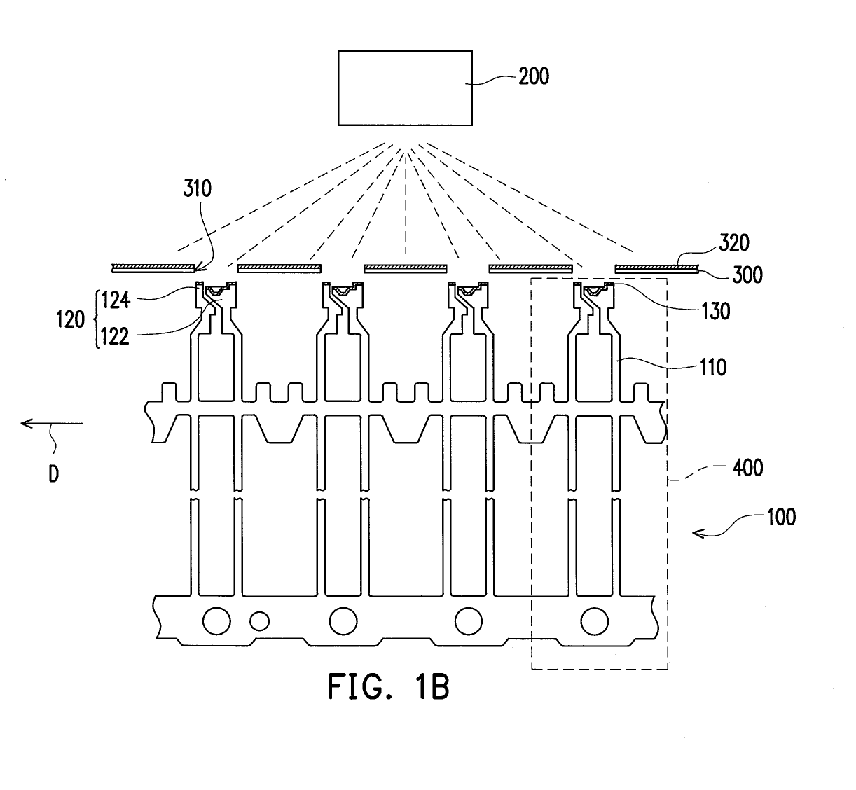

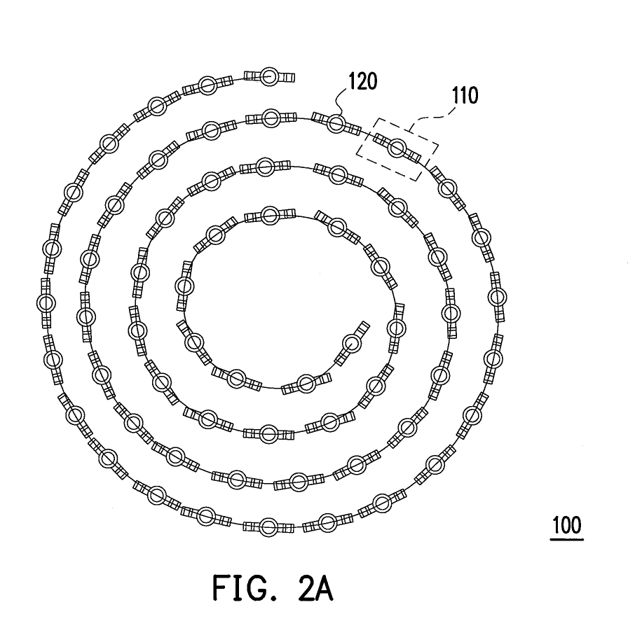

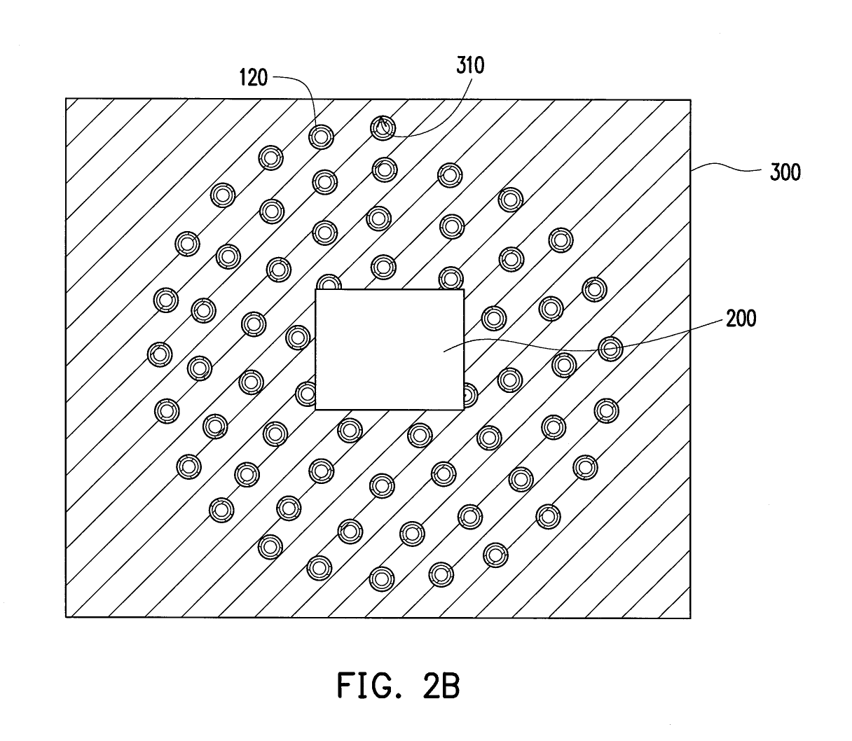

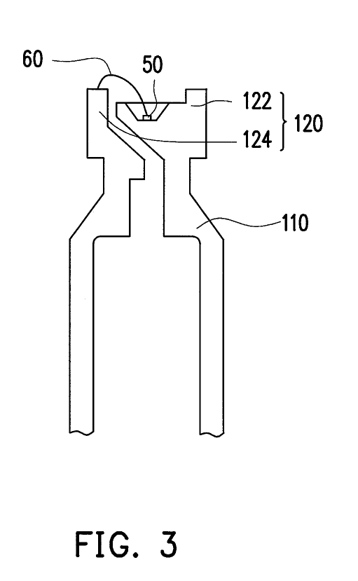

FIGS. 1A and 1B are schematic views illustrating the steps for fabricating a lead frame of a light emitting diode (LED) in accordance with one embodiment of the invention. FIG. 2A is a top view of a conductive frame tape depicted in FIG. 1A. FIG. 2B is a top view of a target, a mask and a conductive frame tape depicted in FIG. 1B. FIG. 3 is a schematic cross-sectional view illustrating an electrical connection depicted in FIG. 1A between a first connection portion and a chip. According to the present embodiment of the invention, a method for fabricating a lead frame of an LED includes the steps described hereinafter. First, referring to FIGS. 1A, 2A, and 3, a conductive frame tape 100 is provided. The conductive frame tape 100 includes a plurality of conductive frames 110 arranged along an extending direction D of the conductive frame tape 100. Each of the conductive frames 110 has a first connection portion 120 adapted to carry an LED chip 50. In the present embodiment of the invention, each of the first connection portions 120 includes a chip carrying area 122 and a wire bonding area 124. The chip carrying area 122 is adapted to carry the LED chip 50. The wire bonding area 124 is adapted to connect with a terminal of a conductive line 60, and another terminal of the conductive line 60 is connected with the LED chip 50.

Next, referring to FIGS. 1B and 2B, a plurality of first sputter layers 130 are selectively sputtered onto the conductive frame tape 100 through a target 200, and the first sputter layers are respectively formed on the first connection portions 120. In the present embodiment of the invention, selectively sputtering the first sputter layers 130 onto the conductive frame tape 100 includes disposing a mask 300 between the target 200 and the conductive frame tape 100. The mask 300 has a plurality of openings 310 for exposing the first connection portions 120. Physical vapor deposition (PVD) can be performed in order to sputter the first sputter layers 130, in which plasma is utilized to bombard the target 200 so as to sputter the material from the target 200. The mask 300 can shield a portion of the sputtered material, and another portion of the sputtered material is deposited on the first connection portions 120 by passing through the openings 310, thereby forming the first sputter layers 130. The sputtered material shielded by the mask 300 is deposited on the mask 300, thereby forming a second sputter layer 320. Consequently, while selectively sputtering the first sputter layers 130 onto the conductive frame tape 100, the second sputter layer 320 is formed on the mask 300. Heretofore, the conductive frames 110 and the first sputter layers 130 form a lead frame 400.

In the present embodiment of the invention, since the material of the first sputter layers 130 comprises silver, the material of the target 200 and the second sputter layer 320 also comprises silver. Silver can improve the conductivity of the lead frame 400, thereby providing a better conductive path for the LED chip (depicted in FIG. 3) and an external power source (not shown). However, in other embodiments of the invention, the first sputter layers 130, the target 200, and the second sputter layer 320 can comprise of other materials.

In the present embodiment of the invention, before selectively sputtering the first sputter layers 130 onto the conductive frame tape 100, the conductive frame tape 100 can be cleaned first so as to remove dirt or contaminants on the conductive frame tape 100. Thereafter, the conductive frame tape 100 can be baked so as to evaporate the leftover liquids from the cleaning of the conductive frame tape 100. Furthermore, after selectively sputtering the first sputter layers onto the conductive frame tape 100, a thickness of the first sputter layers can be measured so as to ensure the quality of the first sputter layers 130. Moreover, after selectively sputtering the first sputter layers onto the conductive frame tape 100, an outer appearance of the first sputter layers 130 can be inspected so as to confirm whether or not defects exist on the first sputter layers 130.

Since the first sputter layers are sputtered onto the conductive frame tape 100 in the present embodiment of the invention for fabricating the lead frame of the LED, the fabrication steps are simple, high output, and the sputter layers have a more uniform thickness.

Moreover, according to the present embodiment of the invention, during fabrication of the lead frame, water is only required during the cleaning of the conductive frame tape 100, and water can be optional for other steps. Therefore, the method for fabricating the lead frame of the LED according to the present embodiment of the invention limits the water needed, thereby reducing manufacturing costs. Compared to conventional electroplating methods, the method for fabricating the lead frame according to the present embodiment of the invention can further avoid the waste management and equipments needed for electroplating, thereby adhering to environmental concerns while reducing costs.

In the present embodiment of the invention, after selectively sputtering the first sputter layers 130 onto the conductive frame tape 100, an electrolytic process can be performed to recover the second sputter layer 320 on the mask 300. For example, the mask 300 can be placed in an electrolytic solution for diffusion of the second sputter layer 320 in the electrolytic solution through electrolysis. Consequently, the second sputter layer 320 can be recovered. Since the method for fabricating the lead frame of the LED according to the present embodiment of the invention selectively sputters the first sputter layers 130 onto the conductive frame tape 100, and the second sputter layer 320 on the mask 300 can be recovered through the electrolytic process, a significant amount of sputter material used can be saved, thereby reducing manufacturing costs.

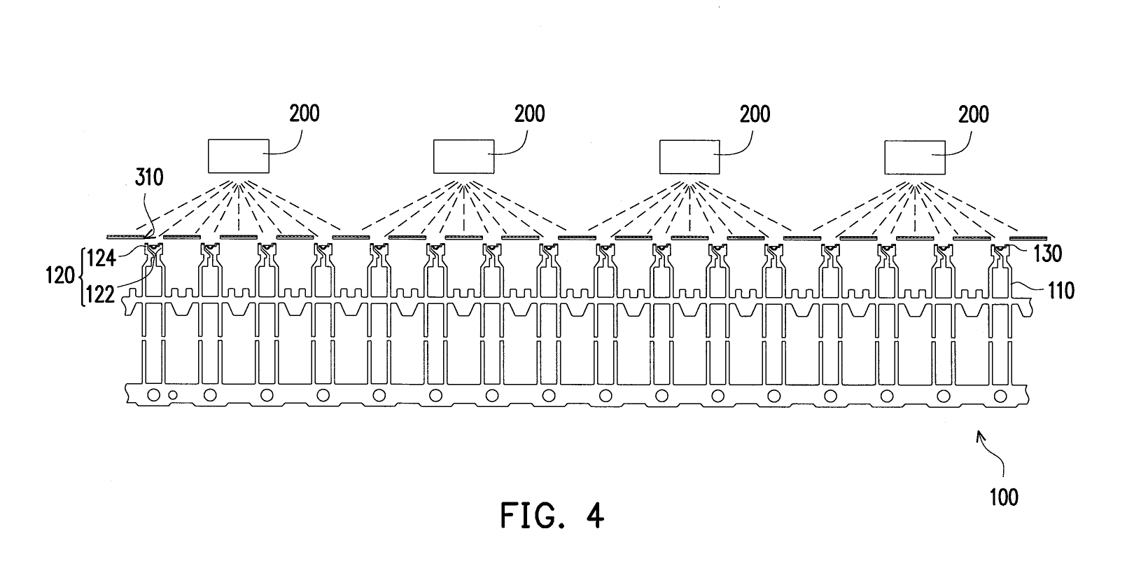

FIG. 4 is a schematic view illustrating a method for fabricating a lead frame of an LED in accordance with another embodiment of the invention. Referring to FIG. 4, the method for fabricating the lead frame of the LED in the present embodiment is similar to the above-described method depicted in FIGS. 1A and 1B. The differences between the two are described hereinafter. In the method for fabricating the lead frame according to the present embodiment of the invention, a plurality of targets 200 are used to sputter the conductive frame tape 100. Moreover, in the present embodiment of the invention, while selectively sputtering the first sputter layers 130 onto the conductive frame tape 100, the conductive frame tape 100 can be moved with respect to the targets 200, so as to sputter the targets 200 in turns onto the conductive frames 110 of the conductive frame tape 100. Consequently, the conductive frame tape 100 can continuously pass by a side of the targets 200, and upon passage thereof, the conductive frames 110 on the conductive frame tape 100 are sputtered. By sputtering in this assembly line manner, the duration of fabrication can be shortened, thereby increasing the output per unit time.

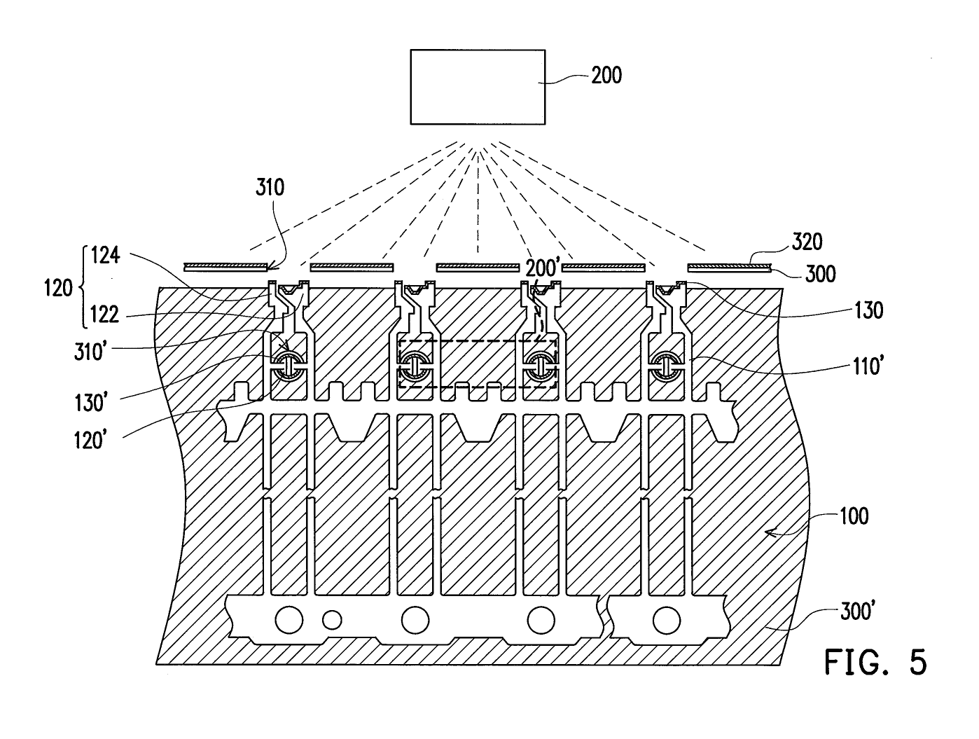

FIG. 5 is a schematic cross-sectional view illustrating a method for fabricating a lead frame of an LED in accordance with another embodiment of the invention. Referring to FIG. 5, the method for fabricating the lead frame of the LED in the present embodiment is similar to the above-described method depicted in FIGS. 1A and 1B. The differences between the two are described hereinafter. In the method for fabricating the lead frame according to the present embodiment of the invention, each of a plurality of conductive frames 110′ further includes a second connection portion 120′, in which the second connection portion 120′ is adapted to electrically connect with another LED chip (not shown) or other electronic devices. While selectively sputtering the first sputter layers 130 onto a conductive frame tape 100′ through the target 200, a plurality of third sputter layers 130′ can be selectively sputtered onto the conductive frame tape 100′ through another target 200′. Moreover, the third sputter layers 130′ are respectively formed on the second connection portions 120′. Specifically, another mask 300′ can be disposed between the target 200′ and the second connection portions 120′, in which the mask 300′ has a plurality of openings 310′ for exposing the second connection portions 120′. Consequently, the third sputter layers 130′ are sputtered onto the second connection portions 120′. In other embodiments of the invention, the same target 200 can be used to sputter the first connection portions 120 and the second connection portions 120′.

It should be noted that embodiments of the invention are not limited by disposing the first connection portions 120 above the conductive frame tape 100 or the conductive frame tape 100′, nor are the embodiments of the invention limited by disposing the second connection portions 120′ above the conductive frame tape 200′. In other embodiments of the invention, the first connection portions 120 and the second connection portions 120′ can be disposed in locations different from their depiction in FIG. 5 (i.e. facing other directions). Furthermore, since the conductive frames 110 and the first connection portions 120 can also be utilized in the packaging of surface mount device (SMD) type LEDs, applicability is not limited to the packaging of bulb-type LEDs.

According to embodiments of the invention, since the sputter layers are sputtered onto the conductive frame tape for fabricating the lead frame of the LED, the fabrication steps are simple, high output, and the sputter layers have a more uniform thickness. Moreover, during fabrication of the lead frame, water is only required during the cleaning of the conductive frame tape, whereas water can be optional for other steps. Therefore, the method for fabricating the lead frame of the LED according to the embodiments of the invention limits the water needed, thereby reducing the manufacturing costs. Compared to conventional electroplating techniques, the method for fabricating the lead frame according to the embodiments of the invention can further avoid the waste management and equipment requirements of electroplating, thereby adhering to environmental concerns while reducing costs.

Furthermore, since the method for fabricating the lead frame of the LED according to the embodiments of the invention selectively sputters the sputter layers onto the conductive frame tape, and the sputter layer formed on the mask can be recovered through the electrolytic process, a larger amount of sputter material can be saved, thereby effectively reducing manufacturing costs.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A method for fabricating a lead frame of a light emitting diode (LED), comprising:
providing a conductive frame tape comprising a plurality of conductive frames arranged along an extending direction of the conductive frame tape, wherein each of the conductive frames has a first connection portion adapted to carry an LED chip; and
selectively sputtering a plurality of first sputter layers onto the conductive frame tape through at least one target, and respectively forming the first sputter layers on the first connection portions, wherein a mask is disposed between the target and the conductive frame tape, and the mask has a plurality of openings for exposing the first connection portions.

2. The method as claimed in claim 1, wherein while selectively sputtering the first sputter layers onto the conductive frame tape, a second sputter layer is formed on the mask.

3. The method as claimed in claim 2, wherein after selectively sputtering the first sputter layers onto the conductive frame tape, the method further comprises performing an electrolytic process to recover the second sputter layer on the mask.

4. The method as claimed in claim 1, wherein each of the first connection portions comprises:
a chip carrying area adapted to carry the LED chip; and
a wire bonding area adapted to connect with a terminal of a conductive line, and another terminal of the conductive line is connected with the LED chip.

5. The method as claimed in claim 1, wherein a material of the first sputter layers comprises silver.

6. The method as claimed in claim 1, wherein while selectively sputtering the first sputter layers onto the conductive frame tape, the method further comprises moving the conductive frame tape with respect to the target.

7. The method as claimed in claim 1, wherein before selectively sputtering the first sputter layers onto the conductive frame tape, the method further comprises:
cleaning the conductive frame tape; and
baking the conductive frame tape.

8. The method as claimed in claim 1, wherein after selectively sputtering the first sputter layers onto the conductive frame tape, the method further comprises measuring a thickness of the first sputter layers.

9. The method as claimed in claim 1, wherein after selectively sputtering the first sputter layers onto the conductive frame tape, the method further comprises inspecting an outer appearance of the first sputter layers.

10. The method as claimed in claim 1, wherein each of the conductive frames further comprises a second connection portion, and while selectively sputtering the first sputter layers onto the conductive frame tape through the target, the method further comprises selectively sputtering a plurality of third sputter layers onto the conductive frame tape through the target or at least one other target, and respectively forming the third sputter layers on the second connection portions.
